(19) United States
(12) Patent Application Publication
(10) Pub. No.: US 2007/0175621 A1
(43) Pub. Date: Aug. 2, 2007

(54) Re-workable metallic TIM for efficient heat exchange

(75) Inventors: Madhav Datta, Milpitas, CA (US); Peng Zhou, Albany, CA (US); James Hom, Redwood City, CA (US); Mark Munch, Los Altos, CA (US); Mark McMaster, Menlo Park, CA (US)

Correspondence Address: HAVERSTOCK & OWENS LLP, 162 NORTH WOLFE ROAD, SUNNYVALE, CA, 94086, US

(73) Assignee: Cooligy, Inc.

(21) Appl. No.: 11/345,556

(22) Filed: Jan. 31, 2006

(51) Int. Cl. H05K 7/20

(52) U.S. Cl. 165/185; 361/704

(57) ABSTRACT

A heat exchanging system uses a metallic TIM for efficient heat transfer between a heat source and a heat exchanger. The heat source is preferably an integrated circuit coupled to a circuit board. The metallic TIM preferably comprises indium. The metallic TIM is comprised of either a separate metallic TIM foil or as a deposited layer of metal material. The metallic TIM foil is mechanically joined to a first surface of the heat exchanger and to a first surface of the integrated circuit by applying sufficient pressure during clamping. Disassembly is accomplished by un-clamping the heat exchanger, the metallic TIM foil, and the integrated circuit from each other. Once disassembled, the heat exchanger and the metallic TIM foil are available to be used again. If the metallic TIM is deposited onto the heat exchanger, disassembly yields a heat exchanging sub-assembly that is also reusable.

### FIELD OF THE INVENTION

The invention relates to an apparatus for cooling a heat producing device and a method of constructing thereof. In particular, the present invention relates to a re-workable metallic TIM for efficient heat exchange.

### BACKGROUND OF THE INVENTION

Operation of an integrated circuit produces heat. As integrated circuits increase in processing power, the production of heat also increases. In current microprocessor assemblies, a heat exchanger is thermally coupled to an integrated circuit, or die, in order to remove the heat produced by the integrated circuit. The heat exchanger is typically positioned above the die. In one approach, the heat exchanger is thermally coupled to the die by means of a polymer thermal interface material (TIM), such as thermally conductive grease. However, polymer TIM has a relatively low thermal conductivity and thus provides a significant barrier for heat transfer from the die to the heat exchanger.

In another approach, a soldering technology is used which involves thermal reflow of a solder material with wetting layers on both the die and the heat exchanger. U.S. Pat. No. 6,504,242 uses such an approach. '242 teaches a heat spreader sub-assembly that includes a primary heat spreader made of copper and a thin nickel layer plated over the copper primary heat spreader. The heat spreader sub-assembly is thermally coupled to a semiconductor package sub-assembly using an indium block and separate wetting layers applied to both the heat spreader sub-assembly and the semiconductor package sub-assembly. In particular, '242 teaches plating a gold layer on a bottom surface of the heat spreader sub-assembly. The gold layer serves as a wetting layer for the indium block during a subsequent reflow process step. Further, a stack of layers are sequentially deposited on a top surface of the semiconductor package sub-assembly. The stack includes titanium, a nickel vanadium alloy, and gold layers which also serve as a wetting layer for the indium block during the subsequent reflow process step.

One disadvantage of using a soldering technology, such as that taught in '242, is that each of the heat exchanger, or heat spreader, and the integrated circuit requires a wet surface to join to the TIM. Such a requirement adds processing steps. Another disadvantage is that the reflow process requires heating and cooling of the TIM, and therefore the integrated circuit, which in addition to requiring an additional processing step may also damage the integrated circuit, or the surrounding sub-assembly. Several of these steps also involve vacuum processing, which adds complexity. Still another disadvantage is that once the reflow process is performed, the process is not re-workable, and the TIM is not reusable.

### SUMMARY OF THE INVENTION

Embodiments of the present invention are directed to a heat exchanging system that uses a metallic TIM for efficient heat transfer between a heat source and a heat exchanger. Preferably, the heat source is an integrated circuit coupled to a circuit board. The metallic TIM preferably comprises indium, which is thermally conductive and a relatively “soft” material. In a first embodiment, a thin metallic TIM foil is positioned between the integrated circuit and the heat exchanger. The metallic TIM foil is mechanically joined to a first surface of the heat exchanger and to a first surface of the integrated circuit by applying sufficient pressure during clamping. Any conventional clamping means can be used which clamps the heat exchanger to the integrated circuit. Such clamping means are well known in the art. Assembly of the heat exchanging system, according to the first embodiment, is a room temperature assembly process. Disassembly is accomplished by un-clamping the heat exchanger, the metallic TIM foil, and the integrated circuit from each other. Once disassembled, the heat exchanger and the metallic TIM foil are available to be used again.

In a second embodiment, a metallic TIM is deposited on the first surface of the heat exchanger, thereby forming a heat exchanging sub-assembly. The metallic TIM is deposited using any conventional means, including, but not limited to, electroplating or e-beam deposition. As in the first embodiment, the metallic TIM on the heat exchanging sub-assembly is mechanically joined to the first surface of the integrated circuit using any conventional clamping means. With the exception of electroplating or e-beam depositing of the metallic TIM onto the heat exchanger, assembly of the heat exchanging system according to the second embodiment is a room temperature assembly process. Disassembly is accomplished by un-clamping the heat exchanging sub-assembly from the integrated circuit. Once disassembled, the heat exchanging sub-assembly is available to be used again.

The heat exchanging system of the present invention provides many advantages. One advantage is that a metallic TIM provides efficient means of exchanging heat. A second advantage is that the assembly process is simplified and is performed at room temperature. A third advantage is that the assembly process is re-workable such that the heat exchanger, the metallic TIM foil, and the heat exchanging sub-assembly are reusable. A fourth advantage is that the compliant property of the metallic TIM provides a cushion for absorbing stresses, thereby minimizing stress transferred from the heat exchanger to the integrated circuit.

These and other advantages will become apparent as embodiments of the heat exchanging system are described according to the detailed description below and the accompany figures.

### BRIEF DESCRIPTION OF THE DRAWINGS

FIG. 1 illustrates components of the heat exchanging system according to a first embodiment of the present invention.

FIG. 2 illustrates components of the heat exchanging system according to the second embodiment.

FIG. 3 illustrates an assembled heat exchanging system.

FIG. 4 illustrates a method of constructing the heat exchanging system of the first embodiment.

FIG. 5 illustrates a method of reusing the components of the assembled heat exchanging system of the first embodiment.

FIG. 6 illustrates a method of constructing the heat exchanging system of the second embodiment.

FIG. 7 illustrates a method of reusing the components of the assembled heat exchanging system of the second embodiment.

Elements that are substantially the same maintain the same reference numerals throughout the figures.

### DETAILED DESCRIPTION OF THE PRESENT INVENTION

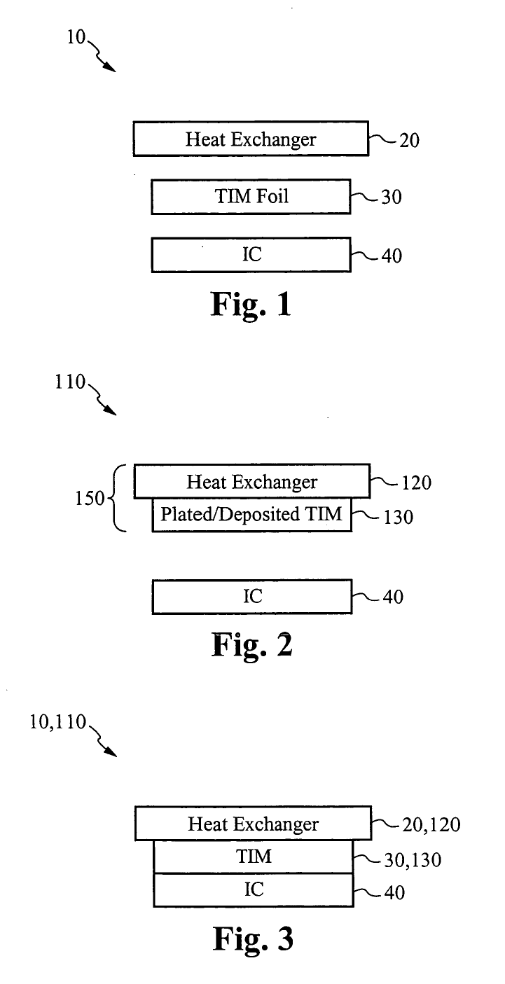

FIG. 1 illustrates components of a heat exchanging system 10 according to a first embodiment of the present invention. The components are illustrated in FIG. 1 before the heat exchanging system 10 is assembled. The heat exchanging system 10 includes a heat exchanger 20, a metallic TIM foil 30 and a heat source 40. Preferably, the heat source 40 is an integrated circuit, although the heat exchanging system 10 can be used to cool any heat generating device. The integrated circuit 40 is preferably coupled to a printed circuit board (not shown). The metallic TIM foil 30 preferably comprises indium. Indium is a relatively compliant, or soft, material. As such, the metallic TIM foil 30, when pressed into contact with the integrated circuit 40, acts as a cushion. In this manner, stress imparted to the integrated circuit 40 is minimized in at least two different ways. First, stress imparted by the weight of the metallic TIM foil 30 and the heat exchanger 20 onto the integrated circuit 40 is substantially absorbed due to the compliant nature of the indium. Second, stress is induced by the clamping pressure used to press the components of the heat exchanging system 10 into place is also minimized. To maximize the effectiveness of the metallic TIM foil 30, a preferred thickness of the indium material is used. If the metallic TIM foil 30 is too thin, then the indium material does not provide sufficient compliance to substantially absorb stress. If the metallic TIM foil 30 is too thick, then the indium material is not sufficiently thermally conductive. The metallic TIM foil 30 preferably has a thickness in the range of about 10 micrometers (microns) to about 2 millimeters (mm). More preferably, the thickness of the metallic TIM foil 30 is in the range of about 25 microns to about 1 mm.

Preferably, the heat exchanger 20 is a liquid-based cooling device. Alternatively, the heat exchanger 20 is any conventional heat exchanging device that accepts heat from another device thermally coupled via a common interface. The heat exchanger 20 is preferably comprised of copper. Alternatively, the heat exchanger 20 is comprised of any heat conducting material. As illustrated in FIG. 1, no wetting layers are used to couple either the heat exchanger 20 to the metallic TIM foil 30, or the integrated circuit 40 to the metallic TIM foil 30.

In a second embodiment of a heat exchanging system, the metallic TIM foil is replaced by a deposited layer of a metal TIM 130. FIG. 2 illustrates components of a heat exchanging system 110 according to the second embodiment. Similarly to FIG. 1, the components are illustrated in FIG. 2 before the heat exchanging system 110 is assembled. The heat exchanging system 110 includes a heat exchanging sub-assembly 150 and the integrated circuit 40. The heat exchanging sub-assembly 150 includes a heat exchanger 120 onto which a layer of metallic TIM 130 is deposited. Preferably, the metallic TIM layer 130 is deposited on a bottom surface of the heat exchanger 120. Alternatively, the metallic TIM layer could be deposited onto the surface of the integrated circuit. Since indium can not be directly deposited on silicon, this alternative approach requires depositing metallic layers, such as Ti/Cu, on the silicon before depositing the indium layer. The heat exchanger 120 preferably functions similarly as the heat exchanger 20 (FIG. 1). The metallic TIM layer 130 preferably comprises indium. The metallic TIM layer 130 is preferably plated or e-beam deposited. Alternatively, the metallic TIM layer 130 is deposited using any conventional means. A thickness of the metallic TIM layer 130 is preferably in the range of about 2 um to 100 um. More preferably, the thickness of the metallic TIM layer 130 is in the range of about 10 um to 30 um.

FIG. 3 illustrates the heat exchanging system 10, 110, as assembled. The metallic TIM 30, 130 is pressed against a top surface of the integrated circuit 40. In this manner, the metallic TIM 30, 130 is mechanically joined to the integrated circuit 40. The metallic TIM 30, 130 is not physically bonded to the integrated circuit 40. In the first embodiment, the metallic TIM foil 30 is also mechanically joined to the heat exchanger 20.

The components are mechanically joined by clamping the heat exchanger 20, 120 to the integrated circuit 40, with the metallic TIM 30, 130 positioned there between. Any conventional clamping means can be used. For example, a clamp or spring urged clamp is used to press and secure the heat exchanger 20, 120 to a circuit board onto which the integrated circuit 40 is connected. As another example, the heat exchanger 20, 120 is secured to the circuit board using screws. Sufficient clamping pressure is applied to generate a thermal interface between the metallic TIM 30, 130 and the integrated circuit 40. In the case of the first embodiment where the metallic TIM foil 30 is a separate component than the heat exchanger 20, sufficient pressure is also applied to generate a thermal interface between the metallic TIM foil 30 and the heat exchanger 20.

Where the individual components are mechanically joined, the components can be disassembled and reused. In the first embodiment, the heat exchanger 20, the metallic TIM foil 30, and the integrated circuit 40 are un-clamped from each other, and the heat exchanger 20 and the metallic TIM foil 30 are individually reusable. In the second embodiment, the heat exchanging sub-assembly 150 is un-clamped from the integrated circuit 40, and the heat exchanging sub-assembly 150 is reusable.

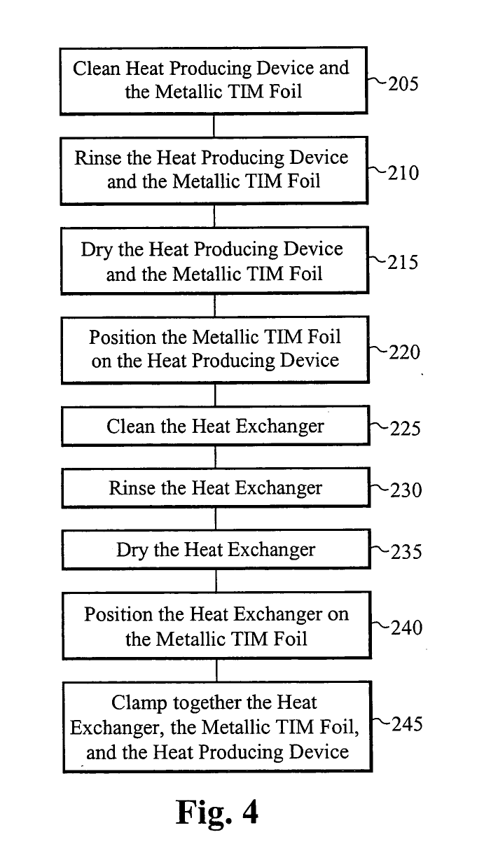

FIG. 4 illustrates a first method of constructing a heat exchanging system. At the step 205, a heat producing device, such as the integrated circuit 40 (FIG. 1), and a metallic TIM foil, such as the metallic TIM foil 30 (FIG. 1), are cleaned. The heat producing device and the metallic TIM foil are preferably cleaned using a 10% HCl solution. Next, at the step 210, the heat producing device and the metallic TIM foil are rinsed, preferably using de-ionized water. At the step 215, the heat producing device and the metallic TIM foil are dried, preferably using acetone. Although steps 205 through 215 describe concurrently cleaning, rinsing, and drying the heat producing device and the metallic TIM foil, the heat producing device and the metallic TIM foil can be cleaned, rinsed, and/or dried independently of each other.

At the step 220, the metallic TIM foil is positioned on the heat producing device. Preferably, the metallic TIM foil is positioned such that a bottom surface of the metallic TIM foil is placed in contact with a top surface of the heat producing device. At the step 225, a heat exchanger, such as the heat exchanger 20 (FIG. 1), is cleaned, preferably using acetone. Cleaning of the heat exchanger can also be done prior to positioning the metallic TIM foil on the heat producing device (step 220). Cleaning of the heat exchanger can also be performed concurrently with drying the heat producing device and the metallic TIM foil using acetone (step 215). At the step 230, the heat exchanger is rinsed, preferably using de-ionized water. At the step 235, the heat exchanger is dried, preferably using acetone.

At the step 240, the heat exchanger is positioned on the metallic TIM foil. Preferably, the heat exchanger is positioned such that a bottom surface of the heat exchanger is placed in contact with a top surface of the metallic TIM foil. At the step 245, the heat exchanger, the metallic TIM foil, and the heat producing device are clamped together to form a heat exchanging system, such as the heat exchanging system 10 (FIG. 3). Clamping these components together mechanically joins the heat exchanger to the metallic TIM foil to generate a first thermal interface, and mechanically joins the metallic TIM foil to the heat producing device to generate a second thermal interface. As a result, heat is transferred from the heat producing device 40 to the metallic TIM foil 30 to the heat exchanger 20 via the first and second thermal interfaces.

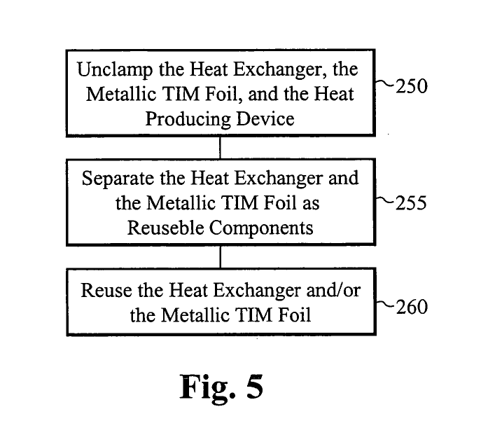

FIG. 5 illustrates a first method of reusing the components of an assembled heat exchanging system. The first method is directed to a heat exchanging system that includes a heat exchanger, such as the heat exchanger 20 (FIG. 1), a metallic TIM foil, such as the metallic TIM foil 30 (FIG. 1), and a heat producing device, such as the integrated circuit 40, clamped together, such as the heat exchanging system 10 (FIG. 3). The first method of reusing components described in relation to FIG. 5 is preferably used to disassemble a heat exchanging system that is assembled using the method described in FIG. 4. Alternatively, the first method of reusing components can be used to disassemble any heat exchanging system that is assembled by clamping together a heat exchanger, a metallic TIM foil, and a heat producing device.

The first method of reusing components begins at the step 250 by un-clamping the heat exchanger 20, the metallic TIM foil 30, and the heat producing device 40. At the step 255, the heat exchanger 20, the metallic TIM foil 30, and the heat producing device 40 are separated from each other. At the step 260, either the separated heat exchanger 20, the separated metallic TIM foil 30, or both are reused in the assembly of another heat exchanging system.

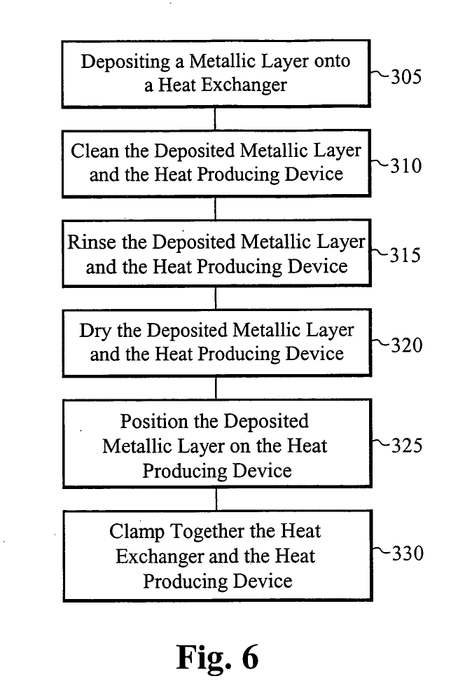

FIG. 6 illustrates a second method of constructing a heat exchanging system. At the step 305, a metallic layer is deposited onto a heat exchanger, such as the heat exchanger 120 (FIG. 2). The metallic layer is preferably deposited on a bottom surface of the heat exchanger. The deposited metal, such as the plated TIM layer 130 (FIG. 2), and the heat exchanger form a heat exchanging sub-assembly, such as the heat exchanging sub-assembly 150 (FIG. 2). Preferably, the deposited metallic layer comprises indium. At the step 310, a heat producing device, such as the integrated circuit 40 (FIG. 2), and the deposited metallic layer are cleaned. The heat producing device and the deposited metallic layer are preferably cleaned using a 10% HCl solution. Next, at the step 315, the heat producing device and the deposited metallic layer are rinsed, preferably using de-ionized water. At the step 320, the heat producing device and the deposited metallic layer are dried, preferably using acetone. Although steps 310 through 320 describe concurrently cleaning, rinsing, and drying the heat producing device and the deposited metallic layer, the heat producing device and the deposited metallic layer can be cleaned, rinsed, and/or dried independently of each other.

At the step 325, the heat exchanging sub-assembly is positioned on the heat producing device. Preferably, the deposited metallic layer of the heat exchanging sub-assembly is positioned such that a bottom surface of the deposited metallic layer is placed in contact with a top surface of the heat producing device. At the step 330, the heat exchanging sub-assembly and the heat producing device are clamped together to form a heat exchanging system, such as the heat exchanging system 110 (FIG. 3). Clamping together these components mechanically joins the deposited metallic layer of the heat exchanging sub-assembly to the heat producing device, thereby generating a thermal interface. As a result, heat is transferred from the heat producing device to the deposited metallic layer to the heat exchanger via the thermal interface.

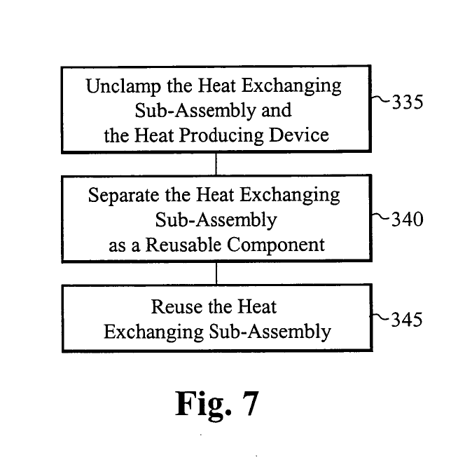

FIG. 7 illustrates a second method of reusing the components of an assembled heat exchanging system. The second method is directed to a heat exchanging system that includes a heat exchanging sub-assembly, such as the heat exchanging sub-assembly 150 (FIG. 2), and a heat producing device, such as the integrated circuit 40, clamped together, such as the heat exchanging system 110 (FIG. 3). The second method of reusing components described in relation to FIG. 7 is preferably used to disassemble a heat exchanging system that is assembled using the method described in FIG. 6. Alternatively, the second method of reusing components can be used to disassemble any heat exchanging system that is assembled by clamping together a heat exchanging sub-assembly that includes a deposited metal TIM layer, and a heat producing device.

The second method of reusing components begins at the step 335 by un-clamping the heat exchanging sub-assembly and the heat producing device. At the step 340, the heat exchanging sub-assembly and the heat producing device are separated from each other. At the step 345, the heat exchanging sub-assembly is reused in the assembly of another heat exchanging system.

In operation, the integrated circuit 40 generates heat, which is transferred through the metallic TIM 30, 130 to the heat exchanger 20, 120 via conduction or convection. In the preferred embodiment where the heat exchanger 20, 120 is liquid-based, the heat is transferred from the integrated circuit 40 to a liquid within the heat exchanger 20, 120. The heated liquid is then pumped out of the heat exchanger 20, 120 to a heat rejector, or other device for cooling the heated liquid. Where the heat exchanger 20, 120 is not liquid-based, for example the heat exchanger 20, 120 is a heat spreader, the heat transferred to the heat exchanger 20, 120 is spread outward through the heat exchanger 20, 120 and is conducted or convected from an outer surface of the heat exchanger 20, 120. It is understood that any other conventional means for removing heat from the heat exchanger 20, 120 can be used.

The present invention has been described in terms of specific embodiments incorporating details to facilitate the understanding of the principles of construction and operation of the invention. Such reference herein to specific embodiments and details thereof is not intended to limit the scope of the claims appended hereto. It will be apparent to those skilled in the art that modifications may be made in the embodiment chosen for illustration without departing from the spirit and scope of the invention.

What is claimed is:

1. A heat exchanging system comprising:
a. a heat exchanger;
b. a heat source; and
c. a metallic thermal interface material thermally coupled between the heat exchanger and the heat source, wherein the metallic thermal interface material is mechanically joined to the heat exchanger.

2. The heat exchanging system of claim 1 wherein the heat exchanger comprises copper.

3. The heat exchanging system of claim 1 wherein the heat exchanger is a thermally conductive heat spreader.

4. The heat exchanging system of claim 1 wherein the heat exchanger is a liquid-based heat exchanger.

5. The heat exchanging system of claim 4 further comprising a heat rejector to receive liquid from and provide liquid to the liquid-based heat exchanger.

6. The heat exchanging system of claim 5 further comprising a pump for pumping the liquid through the heat exchanging system.

7. The heat exchanging system of claim 6 wherein the pump comprises a mechanical pump.

8. The heat exchanging system of claim 6 wherein the pump comprises an electro osmotic pump.

9. The heat exchanging system of claim 1 wherein the heat source comprises an integrated circuit.

10. The heat exchanging system of claim 1 wherein the metallic thermal interface material comprises a deposited or plated metal layer on a first surface of the heat exchanger.

11. The heat exchanging system of claim 10 wherein the deposited or plated metal layer comprises indium.

12. The heat exchanging system of claim 10 wherein the deposited or plated metal layer comprises a thickness in the range of about 2 microns to 100 microns.

13. The heat exchanging system of claim 10 wherein the deposited or plated metal layer comprises a thickness in the range of about 10 microns to 30 microns.

14. The heat exchanging system of claim 1 wherein the metallic thermal interface material comprises a thermal interface material foil.

15. The heat exchanging system of claim 14 wherein the thermal interface material foil is mechanically joined to the heat exchanger.

16. The heat exchanging system of claim 14 wherein the thermal interface material foil comprises indium.

17. The heat exchanging system of claim 14 wherein the thermal interface material foil comprises a thickness in the range of about 10 microns to about 2 millimeters.

18. The heat exchanging system of claim 14 wherein the thermal interface material foil comprises a thickness in the range of about 20 microns to about 1 millimeter.

19. The heat exchanging system of claim 1 further comprising a clamp to mechanically join the metallic thermal interface material to the heat source.

20. A heat exchanging system comprising:
a. a heat exchanger;
b. a heat source; and
c. a metallic thermal interface material thermally coupled between the heat exchanger and the heat source, wherein the metallic thermal interface material is joined to the heat source without using a wetting layer.

21. The heat exchanging system of claim 20 wherein the metallic thermal interface material comprises a deposited or plated metal layer on a first surface of the heat exchanger.

22. The heat exchanging system of claim 21 wherein the deposited or plated metal layer comprises indium.

23. The heat exchanging system of claim 21 wherein the deposited or plated metal layer comprises a thickness in the range of about 2 microns to 100 microns.

24. The heat exchanging system of claim 21 wherein the deposited or plated metal layer comprises a thickness in the range of about 10 microns to 30 microns.

25. The heat exchanging system of claim 21 wherein the heat exchanger and the deposited metal layer are mechanically joined to the heat source such that the deposited metal layer is thermally coupled to the heat source.

26. The heat exchanging system of claim 20 wherein the metallic thermal interface material comprises a thermal interface material foil.

27. The heat exchanging system of claim 26 wherein the thermal interface material foil is mechanically joined to the heat exchanger and to the heat source.

28. The heat exchanging system of claim 26 wherein the thermal interface material foil comprises indium.

29. The heat exchanging system of claim 26 wherein the thermal interface material foil comprises a thickness in the range of about 10 microns to about 2 millimeters.

30. The heat exchanging system of claim 26 wherein the thermal interface material foil comprises a thickness in the range of about 20 microns to about 1 millimeter.

31. The heat exchanging system of claim 20 further comprising a clamp to mechanically join the metallic thermal interface material to the heat source.

32. A heat exchanging system comprising:
a. a heat exchanger;
b. a heat source;
c. a metallic thermal interface material comprising a first surface and a second surface, wherein the first surface of the metallic thermal interface material is thermally coupled to a first surface of the heat exchanger, and the second surface of the metallic thermal interface material is thermally coupled to a first surface of the heat source; and
d. a clamp to mechanically join the heat exchanger to the metallic thermal interface material and to mechanically join the heat source to the metallic thermal interface material.

33. The heat exchanging system of claim 32 wherein the metallic thermal interface material comprises a thermal interface material foil.

34. The heat exchanging system of claim 33 wherein the thermal interface material foil comprises indium.

35. The heat exchanging system of claim 33 wherein the thermal interface material foil comprises a thickness in the range of about 10 microns to about 2 millimeters.

36. The heat exchanging system of claim 33 wherein the thermal interface material foil comprises a thickness in the range of about 20 microns to about 1 millimeter.

37. A heat exchanging system comprising:
a. a heat exchanger;
b. a heat source;
c. a metallic thermal interface material deposited or plated on a first surface of the heat exchanger, wherein the metallic thermal interface material comprises a first surface which is thermally coupled to a first surface of the heat source; and
d. clamping means to mechanically join the first surface of the metallic thermal interface material to the first surface of the heat source.

38. The heat exchanging system of claim 37 wherein the metallic thermal interface material comprises indium.

39. A method of constructing a heat exchanging system, the method comprising:
a. providing a heat exchanger, a metallic thermal interface material foil, and a heat source as three independent components;
b. positioning the metallic thermal interface material foil between the heat exchanger and the heat source;
c. mechanically joining the heat exchanger, the metallic thermal interface material foil, and the heat source, thereby forming a first thermal interface between the heat exchanger and the metallic thermal interface material foil and forming a second thermal interface between the metallic thermal interface material foil and the heat source.

40. The method of claim 39 wherein mechanically joining comprises clamping together the heat exchanger, the metallic thermal interface material foil, and the heat source.

41. The method of claim 40 further comprising un-clamping the heat exchanger, the metallic thermal interface material foil, and the heat source, whereby the heat exchanger, the metallic thermal interface material foil, and the heat source are independent components.

42. The method of claim 41 further comprising re-using either the heat exchanger, the metallic thermal interface material foil, or both to construct another heat exchanging system.

43. The method of claim 39 wherein forming the first thermal interface and the second thermal interface does not include using a wetting layer.

44. The method of claim 39 wherein forming the first thermal interface and the second thermal interface is performed at room temperature.

45. A method of constructing a heat exchanging system, the method comprising:
a. providing a heat exchanger and a heat source as independent components;
b. depositing a layer of metallic thermal interface material onto a first surface of the heat exchanger, thereby forming a heat exchanging sub-assembly;
c. positioning the heat exchanging sub assembly on the heat source;
c. mechanically joining the heat exchanging sub-assembly to the heat source such that a thermal interface is formed between the deposited metallic thermal interface material.

46. The method of claim 45 wherein mechanically joining comprises clamping together the heat exchanging sub-assembly and the heat source.

47. The method of claim 46 further comprising un-clamping the heat exchanging sub-assembly and the heat source, whereby the heat exchanging sub-assembly and the heat source are independent components.

48. The method of claim 47 further comprising re-using the heat exchanging sub-assembly to construct another heat exchanging system.

49. The method of claim 45 wherein forming the thermal interface does not include using a wetting layer.

50. The method of claim 45 wherein forming the thermal interface is performed at room temperature.

51. A method of constructing a heat exchanging system, the method comprising:
a. providing a heat exchanger, an indium foil, and a semiconductor die as three independent components;
b. cleaning the semiconductor die and the indium foil with 10% HCl solution;
c. rinsing the semiconductor die and the indium foil with de-ionized water;
d. drying the semiconductor die and the metallic thermal interface material foil with acetone;
e. positioning the indium foil on the semiconductor die;
f. cleaning the heat exchanger with acetone;
g. positioning the heat exchanger on the indium foil; and
h. clamping together the heat exchanger, the indium foil, and the semiconductor die.

52. A method of constructing a heat exchanging system, the method comprising:
a. providing a heat exchanger and a semiconductor die as independent components;
b. electroplating an indium film on a first surface of the heat exchanger to form a heat exchanging sub-assembly;
c. cleaning the plated indium with 10% HCl solution;
d. rinsing the plated indium with de-ionized water;
e. drying the plated indium with acetone;
f. cleaning the semiconductor die with 10% HCl solution;
g. rinsing the semiconductor die with de-ionized water;
h. drying the semiconductor die with acetone;
g. positioning the plated indium on the semiconductor die; and
h. clamping together the heat exchanging sub-assembly and the semiconductor die.
